(19) United States
(12) Patent Application Publication
(10) Pub. No.: US 2008/0023761 A1
(43) Pub. Date: Jan. 31, 2008

(54) Semiconductor devices and methods of fabricating the same

(75) Inventors: Mu-Kyeng Jung, Suwon-si (KR); Xiao Quan Wang, Yongin-si (KR); Bai-Sun Kong, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/819,606

(22) Filed: Jun. 28, 2007

(30) Foreign Application Priority Data
Jul. 28, 2006 (KR) 10-2006-0071637

(51) Int. Cl. H01L 29/78; H01L 21/336

(52) U.S. Cl. 257/336; 438/291; 257/E29.256; 257/E21.417

(57) ABSTRACT

Semiconductor devices and methods of fabricating the same are provided. According to an example embodiment, a semiconductor device may include an active region disposed in a substrate and having first conductivity type impurity ions, a gate electrode crossing on the active region, a source region disposed within the active region at one a first side of the gate electrode, a drain region disposed within the active region at the a second side of the gate electrode, a source lightly doped drain (LDD) region disposed within the active region, extending toward the gate electrode from the source region, and having second conductivity type impurity ions, a drain LDD region disposed within the active region, extending toward the gate electrode from the drain region, and having the second conductivity type impurity ions in a concentration higher than the source LDD region, and a first halo region disposed within the active region, surrounding the source LDD region, and having the first conductivity type impurity ions.

### PRIORITY STATEMENT

This application claims priority under 35 U.S.C. § 119 to Korean Patent Application No. 2006-0071637, filed Jul. 28, 2006 in the Korean Intellectual Property Office (KIPO), the entire contents of which are hereby incorporated by reference.

### BACKGROUND

1. Field

Example embodiments relate to semiconductor devices, for example, to transistors with relatively higher output resistance, and methods of fabricating the same.

2. The Convention Art

The increasing integration of semiconductor devices has prompted research into reduction of the channel region of a transistor. Such reduction in the channel region may increase off-current of transistors, which in turn causes an increase in the standby power consumption of transistors. Forming halo regions within the channel region may be employed in order to suppress increase an off-current. The halo regions are generally disposed near source and drain regions, and located within the channel region.

A transistor having a relatively low off-current may be implemented using halo regions. However, halo regions formed adjacent to the drain region may cause an output resistance of the transistor to decrease.

FIG. 1 is a cross-sectional view of a conventional semiconductor device.

Conventionally, an isolation layer 13 defining an active region 12 may be disposed in a predetermined (or alternatively, a given) or desired region of a semiconductor substrate 11. The active region 12 may have p-type impurity ions. A gate electrode 16 may be disposed crossing over the active region 12, a gate oxide layer 15 is disposed between the gate electrode 16 and the active region 12, and spacers 21 are disposed on both sidewalls of the gate electrode 16.

A source region 23S and a drain region 23D may be disposed within the active region 12 outside the spacers 21. The source region 23S and the drain region 23D may have a relatively high concentration of n-type impurity ions. A source lightly doped drain (LDD) region 19S and a drain LDD region 19D may be disposed within the active region 12 below the spacers 21. The source LDD region 19S may be in contact with the source region 23S, and the drain LDD region 19D may be in contact with the drain region 23D.

The source LDD region 19S and the drain LDD region 19D may have a relatively low concentration of n-type impurity ions. The source LDD region 19S and the drain LDD region 19D have substantially the same concentration of n-type impurity ions.

A first halo region 17S, which surrounds the source LDD region 19S and is partially in contact with the source region 23S, is disposed within the active region 12. In addition, a second halo region 17D, which surrounds the drain LDD region 19D and is partially in contact with the drain region 23D, is disposed within the active region 12. The first halo region 17S and the second halo region 17D may have a higher concentration of p-type impurity ions than the active region 12. The first halo region 17S and the second halo region 17D have substantially the same concentration of p-type impurity ions.

The first halo region 17S may act to decrease the off-current of the transistor. In contrast, the second halo region 17D may deteriorate channel length modulation and drain induced barrier lowering (DIBL). Accordingly, the output resistance of the transistor decreases.

The decrease in output resistance makes it difficult to control drain saturation current. That is, transistors having a halo region formed adjacent to their drain region may show a characteristic of increasing drain current with increasing drain voltage.

Another method of implementing a transistor is disclosed in U.S. Pat. No. 6,465,315B1, entitled “MOS Transistor with Local Channel Compensation Implant”, to Yu.

However, techniques of implementing transistors having higher output resistances may need to be continuously improved.

### SUMMARY

Example embodiments may provide semiconductor devices having higher output resistances and/or suppressed channel length modulation.

Example embodiments may provide methods of fabricating semiconductor devices having higher output resistances.

According to an example embodiment, a semiconductor device may include an active region disposed in a substrate and having first conductivity type impurity ions, a gate electrode crossing on the active region, a source region disposed within the active region at one a first side of the gate electrode, a drain region disposed within the active region at the a second other side of the gate electrode, a source lightly doped drain (LDD) region disposed within the active region, extending toward the gate electrode from the source region, and having second conductivity type impurity ions, a drain LDD region disposed within the active region, extending toward the gate electrode from the drain region, and having the second conductivity type impurity ions in a concentration higher than the source LDD region, and a first halo region disposed within the active region, surrounding the source LDD region, and having the first conductivity type impurity ions.

According to an example embodiment, a method of fabricating a semiconductor device may include forming a gate electrode on an active region of a substrate, the active region having first conductivity type impurity ions, forming a source lightly doped drain (LDD) region of a second conductivity type impurity ions at a first side of the gate electrode, forming a drain LDD region of the second conductivity type impurity ions in a concentration higher than the source LDD region at a second side of the gate electrode, forming a first halo region surrounding the source LDD region, forming spacers on both sidewalls of the gate electrode, and forming a source region and a drain region within the active region outside the spacers.

In at least one example embodiment, a semiconductor device may include an active region disposed in a substrate. The active region may have first conductivity type impurity ions. A gate electrode may be disposed on the active region. A source region may be disposed within the active region at one side of the gate electrode. A drain region may be disposed within the active region at the other side of the gate electrode. A source LDD region, which extends toward the gate electrode from the source region, may be disposed within the active region. The source LDD region may have second conductivity type impurity ions. A drain LDD region, which extends toward the gate electrode from the drain region, may be disposed within the active region. The drain LDD region may have the second conductivity type impurity ions in a concentration higher than the source LDD region. A first halo region surrounding the source LDD region may be disposed within the active region. The first halo region may have the first conductivity type impurity ions.

According to example embodiments, the first halo region may be partially in contact with the source region. In addition, the first halo region may have the first conductivity type impurity ions in a concentration higher than the active region. Further, the first halo region may include an inner halo region in contact with the source LDD region. In at least one example embodiment, an outer halo region covering the inner halo region may be provided. The inner halo region may have the first conductivity type impurity ions in a concentration higher than the outer halo region.

In an example embodiment, a second halo region surrounding the drain LDD region may be provided within the active region. The second halo region may have the first conductivity type impurity ions in a concentration lower than the first halo region.

In an example embodiment, the first conductivity type may be n-type or p-type. The second conductivity type may be p-type if the first conductivity type is n-type, and may be n-type if the first conductivity type is p-type.

In an example embodiment, an isolation layer may be provided in the substrate. The isolation layer may act to define the active region.

In an example embodiment, spacers may be disposed on both sidewalls of the gate electrode.

According to example embodiments a method of fabricating a semiconductor device may include preparing a substrate having an active region. The active region may have first conductivity type impurity ions. A gate electrode may be formed to cross the active region. Second conductivity type impurity ions may be implanted into the active region at one side of the gate electrode to form a source LDD region. The second conductivity type impurity ions may be implanted into the active region at the other side of the gate electrode to form a drain LDD region. The drain LDD region may have the second conductivity type impurity ions in a concentration higher than the source LDD region. The first conductivity type impurity ions may be implanted into the active region at one side of the gate electrode to form a first halo region surrounding the source LDD region. Spacers may be formed on both sidewalls of the gate electrode. A source region and a drain region may be formed within the active region outside the spacers.

In an example embodiment, the second conductivity type impurity ions may be implanted into the active region at the other side of the gate electrode to form an initial LDD region while the source LDD region is formed. In this case, the drain LDD region may be formed by implanting the second conductivity type impurity ions in a concentration higher than the source LDD region into the initial LDD region.

In an example embodiment, forming the first halo region may include implanting the first conductivity type impurity ions into the active region at one side of the gate electrode to form an outer halo region. The first conductivity type impurity ions may be implanted into the outer halo region to form an inner halo region.

In an example embodiment, the first conductivity type impurity ions may be implanted into the active region at the other side of the gate electrode to form a second halo region surrounding the drain LDD region while the outer halo region is formed. The second halo region may be formed to have the first conductivity type impurity ions in a concentration lower than the first halo region.

According to example embodiments, a method of fabricating a semiconductor device may include preparing a substrate having an active region. The active region may have first conductivity type impurity ions. A gate electrode may be formed to cross the active region. The first conductivity type impurity ions may be implanted into the active region at one side of the gate electrode to form a first halo region. Second conductivity type impurity ions may be implanted into the first halo region to form a source LDD region. The second conductivity type impurity ions may be implanted into the active region at the other side of the gate electrode to form a drain LDD region. The drain LDD region may have the second conductivity type impurity ions in a concentration higher than the source LDD region. Spacers may be formed on both sidewalls of the gate electrode. A source region and a drain region may be formed within the active region outside the spacers.

In an example embodiment, forming the first halo region may include implanting the first conductivity type impurity ions into the active region at one side of the gate electrode to form an outer halo region. The first conductivity type impurity ions may be implanted into the outer halo region to form an inner halo region.

In an example embodiment, the first conductivity type impurity ions may be implanted into the active region at the other side of the gate electrode to form a second halo region while the outer halo region is formed.

In an example embodiment, the drain LDD region may be formed within the second halo region.

### BRIEF DESCRIPTION OF THE DRAWINGS

Example embodiments will become more apparent from detailed description thereof, including detailed description of the accompanying drawings wherein:

FIG. 1 is a cross-sectional view of a conventional semiconductor device;

FIGS. 2 to 7 are cross-sectional views illustrating semiconductor devices and methods of fabricating the same, according to an example embodiment;

FIGS. 8 to 12 are cross-sectional views illustrating semiconductor devices and methods of fabricating the same, according to example embodiments; and

FIG. 13 illustrates a semiconductor device, according to an example embodiment.

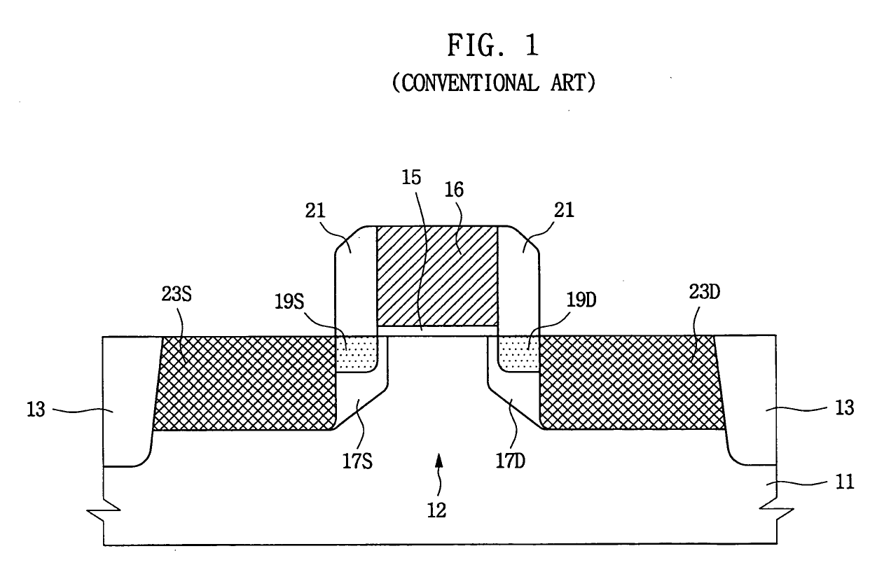

### DETAILED DESCRIPTION OF EXAMPLE EMBODIMENTS

Detailed illustrative embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

It will be understood that if an element or layer is referred to as being “on,” “against,” “connected to” or “coupled to” another element or layer, then it can be directly on, against connected or coupled to the other element or layer, or intervening elements or layers may be present. In contrast, if an element is referred to as being “directly on”, “directly connected to” or “directly coupled to” another element or layer, then there are no intervening elements or layers present. Like numbers refer to like elements throughout. As used herein, the term “and/or” includes any and all combinations of one or more of the associated listed items.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Example embodiments will now be described more fully hereinafter with reference to the accompanying drawings, in which example embodiments are shown. Example embodiments may, however, be embodied in different forms and should not be construed as limited to the example embodiments set forth herein. Rather, example embodiments are provided so that this disclosure will be thorough and complete, and will fully convey the scope of the invention to those skilled in the art. In the drawings, the thickness of layers and regions are exaggerated for clarity. In addition, when a layer is described to be formed on other layer or on a substrate, which means that the layer may be formed on the other layer or on the substrate, or a third layer may be interposed between the layer and the other layer or the substrate. Like numbers refer to like elements throughout the specification, and the drawings should not be considered as being drawn to scale, as some features therein have been exaggerated for clarity and ease of understanding of the aspects set forth therein.

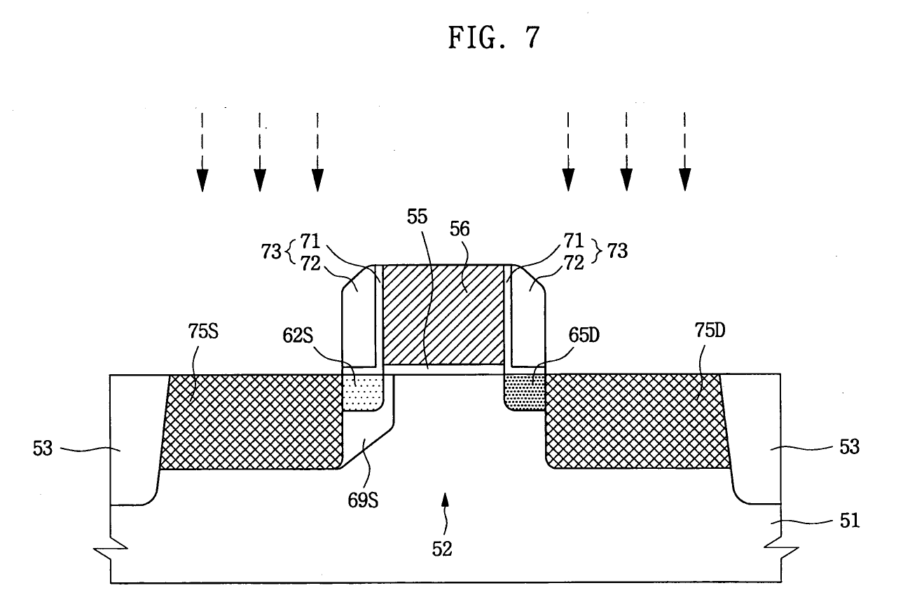

A semiconductor device according to an example embodiment will now be described with reference to FIG. 7.

Referring to FIG. 7, a semiconductor device may include an active region 52 disposed in a substrate 51. The active region 52 may have first conductivity type impurity ions. The substrate 51 may be a semiconductor substrate such as a silicon wafer. The substrate 51 may have the first conductivity type impurity ions. An isolation layer 53 defining the active region 52 may be disposed in a predetermined (or alternatively, a given) or desired region of the substrate 51.

A gate electrode 56 may cross above or be on the active region 52. A gate dielectric layer 55 may be between the active region 52 and the gate electrode 56. The gate dielectric layer 55 may be a thermal oxide layer or a high-k dielectric layer. For example, a high-k dielectric layer may be a layer formed of or including high-k dielectric material such as Ta₂O₅, Al₂O₃, and/or TiO2. However, these are merely examples of dielectric materials and should not be construed as limiting. The gate electrode 56 may be a conductive material layer such as a polysilicon layer, a metal silicide layer, a metal layer, and/or any suitable conductive layer.

Spacers 73 may be disposed on sidewalls of the gate electrode 56. The spacers 73 may have inner spacers 71 and outer spacers 72. The inner spacers 71 may be in contact with the sidewalls of the gate electrode 56. The outer spacers 72 may cover the inner spacers 71.

A source region 75S may be disposed within the active region 52 at one side of the gate electrode 56. A drain region 75D may be disposed within the active region 52 at the other side of the gate electrode 56. The source region 75S and the drain region 75D may be arranged outside the spacers 73. The source region 75S and the drain region 75D may be disposed above the bottom of the isolation layer 53. The source region 75S and the drain region 75D may have a relatively high concentration of second conductivity type impurity ions.

A source LDD region 62S, which extends toward the gate electrode 56 from the source region 75S, may be disposed within the active region 52. The source LDD region 62S may have the second conductivity type impurity ions. A drain LDD region 65D, which extends toward the gate electrode 56 from the drain region 75D, may be disposed within the active region 52. The drain LDD region 65D may have the second conductivity type impurity ions in a concentration higher than the source LDD region 62S.

The source LDD region 62S and the drain LDD region 65D may have the second conductivity type impurity ions in a concentration lower than the source region 75S and the drain region 75D. The source LDD region 62S and the drain LDD region 65D may be arranged under the spacers 73. In addition, the source LDD region 62S and the drain LDD region 65D may be arranged at both sides of the gate electrode 56.

The source LDD region 62S and the drain LDD region 65D may be disposed to a predetermined (or alternatively, a given) depth from the surface of the active region 52. The source LDD region 62S and the drain LDD region 65D may be disposed above the bottoms of the source region 75S and the drain region 75D.

A first halo region 69S surrounding the source LDD region 62S may be disposed within the active region 52. The first halo region 69S may have the first conductivity type impurity ions in a concentration higher than the active region 52. The first halo-region 69S may partially overlap the gate electrode 56. In addition, the first halo region 69S may be partially in contact with the source region 75S.

The first conductivity type may be n-type or p-type. The second conductivity type may be the p-type if the first conductivity type is the n-type, and may be the n-type if the first conductivity type is the p-type.

As described above, the semiconductor device according to example embodiments may include the first halo region 69S, the source LDD region 62S, and the drain LDD region 65D. Accordingly, a channel region of the semiconductor device may have a sloped doping profile. Therefore, it may be possible to implement a semiconductor device having a relatively high output resistance through suppression of channel length modulation.

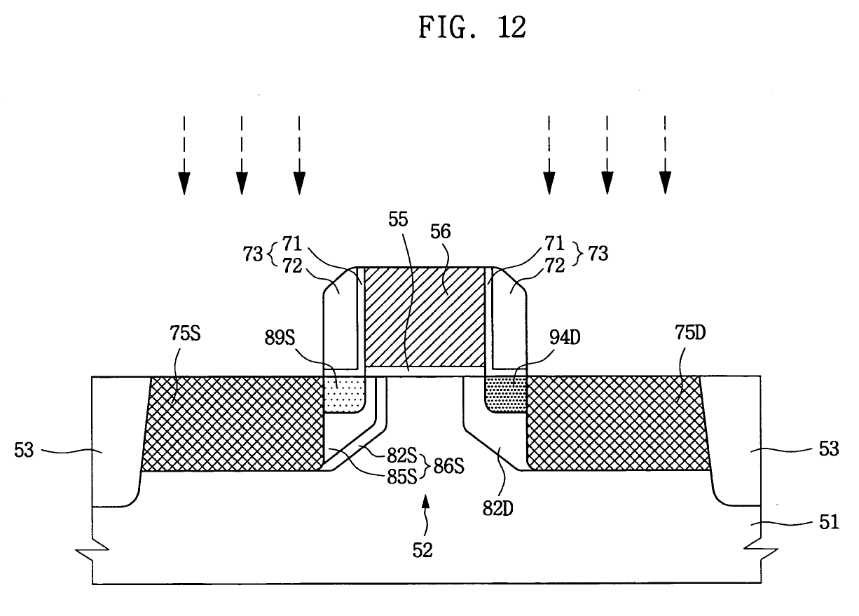

Next, a semiconductor device according to an example embodiment will be described with reference to FIG. 12.

Referring to FIG. 12, the semiconductor device may include an active region 52 disposed in a substrate 51. The active region 52 may have first conductivity type impurity ions. The substrate 51 may be a semiconductor substrate such as a silicon wafer. The substrate 51 may have the first conductivity type impurity ions. An isolation layer 53 defining the active region 52 may be disposed in a predetermined (or alternatively, a given) or desired region of the substrate 51.

A gate electrode 56 may cross above or be disposed on the active region 52. A gate dielectric layer 55 may be interposed between the active region 52 and the gate electrode 56. The gate dielectric layer 55 may be a thermal oxide layer or a high-k dielectric layer. The gate electrode 56 may be a conductive material layer such as a polysilicon layer, a metal suicide layer, a metal layer, and/or any suitable conductive layer.

Spacers 73 may be disposed on sidewalls of the gate electrode 56. The spacers 73 may include inner spacers 71 and outer spacers 72. The inner spacers 71 may be in contact with the sidewalls of the gate electrode 56. The outer spacers 72 may cover the inner spacers 71.

A source region 75S may be disposed within the active region 52 at one side of the gate electrode 56. A drain region 75D may be disposed within the active region 52 at the other side of the gate electrode 56. The source region 75S and the drain region 75D may be arranged outside the spacers 73. The source region 75S and the drain region 75D may be disposed above the bottom of the isolation layer 53. The source region 75S and the drain region 75D may have a relatively high concentration of second conductivity type impurity ions.

A source LDD region 89S, which extends toward the gate electrode 56 from the source region 75S, may be disposed within the active region 52. The source LDD region 89S may have the second conductivity type impurity ions. A drain LDD region 94D, which extends toward the gate electrode 56 from the drain region 75D, may be disposed within the active region 52. The drain LDD region 94D may have the second conductivity type impurity ions in a concentration higher than the source LDD region 89S.

The source LDD region 89S and the drain LDD region 94D may have the second conductivity type impurity ions in a concentration lower than the source region 75S and the drain region 75D. The source LDD region 89S and the drain LDD region 94D may be arranged below the spacers 73. In addition, the source LDD region 89S and the drain LDD region 94D may be arranged at both sides of the gate electrode 56.

The source LDD region 89S and the drain LDD region 94D may be disposed to a predetermined (or alternatively, a given) or desired depth from the surface of the active region 52. The source LDD region 89S and the drain LDD region 94D may be disposed above the bottoms of the source region 75S and the drain region 75D.

A first halo region 86S surrounding the source LDD region 89S may be disposed within the active region 52. The first halo region 86S may have the first conductivity type impurity ions in a concentration higher than the active region 52. The first halo region 86S may partially overlap the gate electrode 56. In addition, the first halo region 86S may be partially in contact with the source region 75S.

The first halo region 86S may include an outer halo region 82S and an inner halo region 85S. For example, the inner halo region 85S may surround the source LDD region 89S. The outer halo region 82S may cover the inner halo region 85S. Alternatively, the outer halo region 82S may be omitted. For example, the inner halo region 85S may have a concentration of the first conductivity type ions in a concentration higher than a concentration of the outer halo region 82S.

A second halo region 82D surrounding the drain LDD region 94D may be disposed within the active region 52. The second halo region 82D may have the first conductivity type impurity ions in a concentration higher than the active region 52 and lower than the first halo region 86S. The second halo region 82D may partially overlap the gate electrode 56. In addition, the second halo region 82D may be partially in contact with the drain region 75D. Alternatively, the second halo region 82D may be omitted.

The first conductivity type may be n-type or p-type. The second conductivity type may be p-type if the first conductivity type is n-type, and may be n-type if the first conductivity type is the p-type.

As described above, the semiconductor device according to example embodiments may include the first halo region 86S, the second halo region 82D, the source LDD region 89S, and the drain LDD region 94D. Accordingly, a channel region of the semiconductor device may have a sloped doping profile. Therefore, it may be possible to implement a semiconductor device having a relatively high output resistance through suppression of channel length modulation.

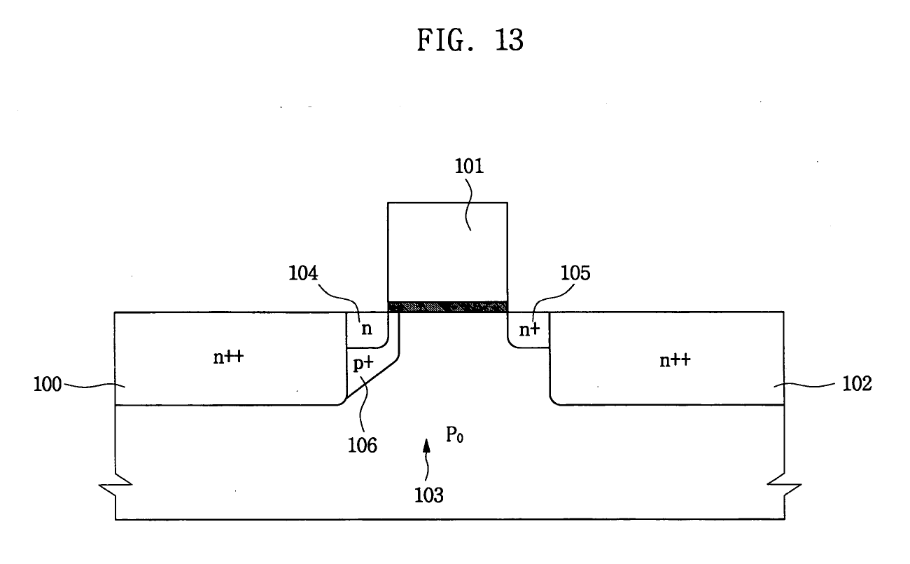

FIG. 13 illustrates a semiconductor device, according to an example embodiment.

As illustrated in FIG. 13, a semiconductor device may include a source 100, a gate 101, an active region 103, and a drain 102. The semiconductor device may further include a source LDD region 104 and a drain LDD region 105. For example, the source LDD region 104 and drain LDD region 105 may be on either side of the active region 103, disposed near the source 100 and drain 102, respectively. The semiconductor device may further include a first halo region 106, doped with an impurity having a conductivity substantially similar to the active region 103. The first halo region 106 may surround the source LDD region 104.

As illustrated in FIG. 13, given by way of example only in an attempt to further convey the concepts of example embodiments, the active region 103 may be p-type, having a doping concentration of p₀. The source 100 and drain 102 may be n-type, having a doping concentration n++. The first halo region 106 may be p-type, and have a doping concentration of p+. The source LDD region 104 and drain LDD region 105 may be n-type, having doping concentrations of n ad n+, respectively. It will be understood that these doping concentrations and dopant types are illustrative only, and in no way limiting. For example, opposite dopant types and different doping concentrations could just as easily be applied in example embodiments.

According to example embodiments, with reference to FIG. 13, the doping concentration of the drain LDD region 105 may be relatively higher than the source LDD region 104, denoted by n+>n in FIG. 13. The doping concentrations of the drain 102 and source 100 may both be relatively higher than the drain LDD region 105, denoted by n++>n+>n in FIG. 13. Therefore, both the doping concentrations of the drain 102 and source 100 may be relatively higher than that of the source LDD region 104. The relationship between the doping concentrations of the source 100 and drain 102 are irrelevant in this example.

According to example embodiments, with reference to FIG. 13, the doping concentration of the first halo region 106 may be relatively higher than that of the active region 103, denoted by p+>p₀. However, the doping concentration of the first halo region 106 may also be substantially similar to that of the active region 103 in other example embodiments. Operative and other features of FIG. 13 are substantially similar to those of FIG. 7 and 12; therefore, detailed discussion will be omitted herein for the sake of brevity.

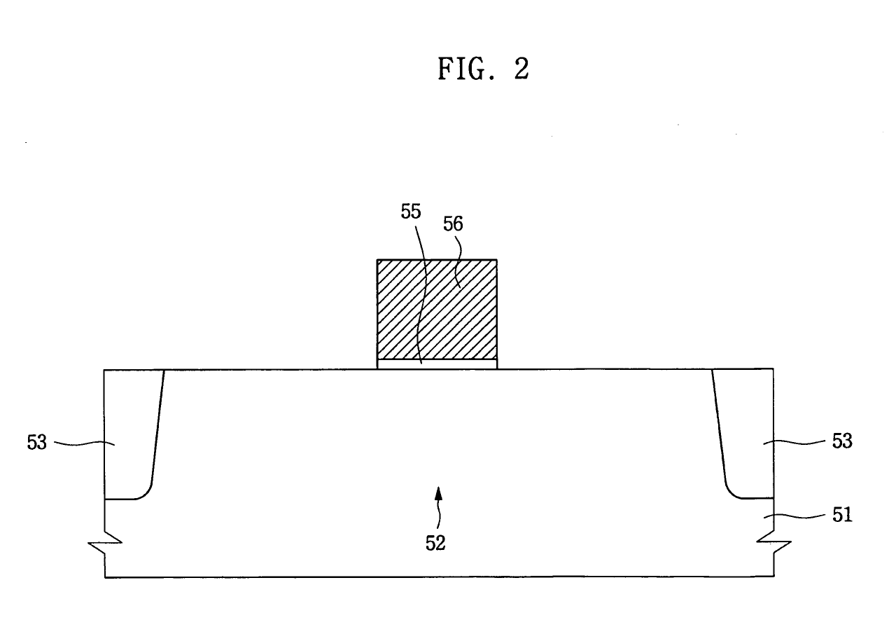

A method of fabricating a semiconductor device according to an example embodiment will now be described with reference to FIG. 2 to 7.

Referring to FIG. 2, an isolation layer 53 defining an active region 52 may be formed in a predetermined (or alternatively, a given) or desired region of a substrate 51.

The substrate 51 may be a semiconductor substrate such as a silicon wafer. The substrate 51 may have first conductivity type impurity ions. The first conductivity type may be an n− or p-type. The isolation layer 53 (e.g., isolation region or trenches) may be formed using well-known shallow trench isolation (STI) techniques. The isolation layer 53 may be formed of an insulating material layer such as a silicon oxide layer and/or any other suitable insulating material.

Subsequent to forming the isolation layer 53, the first conductivity type impurity ions may be implanted into the active region 52. If the first conductivity type is p-type, the process of implanting the first conductivity type impurity ions may use a source containing boron (B) or boron difluoride (BF₂) or any other suitable p-type dopant. If the first conductivity type is n-type, the process of implanting the first conductivity type impurity ions may use a source containing arsenic (As) or phosphorus (P) or any other suitable n-type dopant. For example, the first conductivity type impurity ions may be implanted using a source containing boron difluoride (BF₂). The first conductivity type impurity ions may be implanted with various energies and at various angles using an ion implantation apparatus.

A gate dielectric layer 55 and a gate electrode 56 may be sequentially formed on the substrate 51 having the isolation layer 53. The gate dielectric layer 55 may be formed to cover or partially cover the active region 52. The gate dielectric layer 55 may be formed of a thermal oxide layer or a high-k dielectric layer. The gate electrode 56 may be formed to cross above, or be disposed on, the active region 52. The gate electrode 56 may be formed of a conductive material layer such as a polysilicon layer, a metal silicide layer, a metal layer and/or any suitable conductive material. For example, the gate electrode 56 may be formed to have a gate length not less than 0.1 um.

Patterns such as mask patterns (not shown) may be formed on the gate electrode 56; however, they are omitted for simplicity of description.

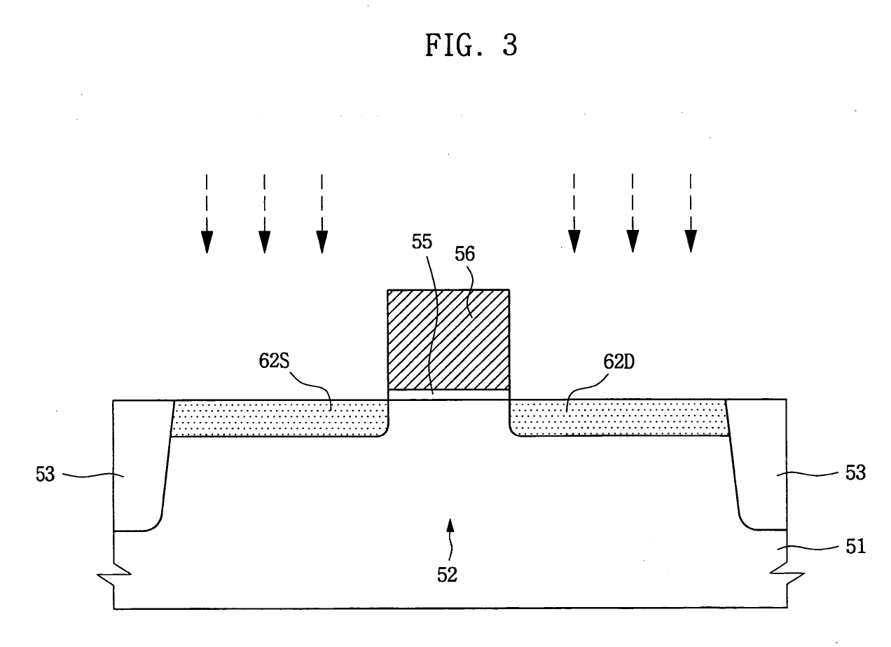

Referring to FIG. 3, second conductivity type impurity ions may be implanted into the substrate 51 having the gate electrode 56. The second conductivity type may be opposite to the first conductivity type. That is, the second conductivity type may be the p-type if the first conductivity type is the n-type, and may be the n-type if the first conductivity type is the p-type. For example, the second conductivity type impurity ions may be implanted using a source containing arsenic (As). The second conductivity type impurity ions may be implanted with various energies and at various angles using an ion implantation apparatus.

A source LDD region 62S may be formed in the active region 52 at one side of the gate electrode 56. In addition, an initial LDD region 62D may be formed in the active region 52 at the other side of the gate electrode 56. The source LDD region 62S and the initial LDD region 62D may be formed to a predetermined (or alternatively, a given) or desired depth from the surface of the active region 52. For example, the source LDD region 62S and the initial LDD region 62D may be disposed above the bottom of the isolation layer 53. In addition, the source LDD region 62S and the initial LDD region 62D may be arranged at both sides of the gate electrode 56.

Alternatively, the initial LDD region 62D may be omitted. That is, the source LDD region 62S may be selectively formed in the active region 52 at one side of the gate electrode 56.

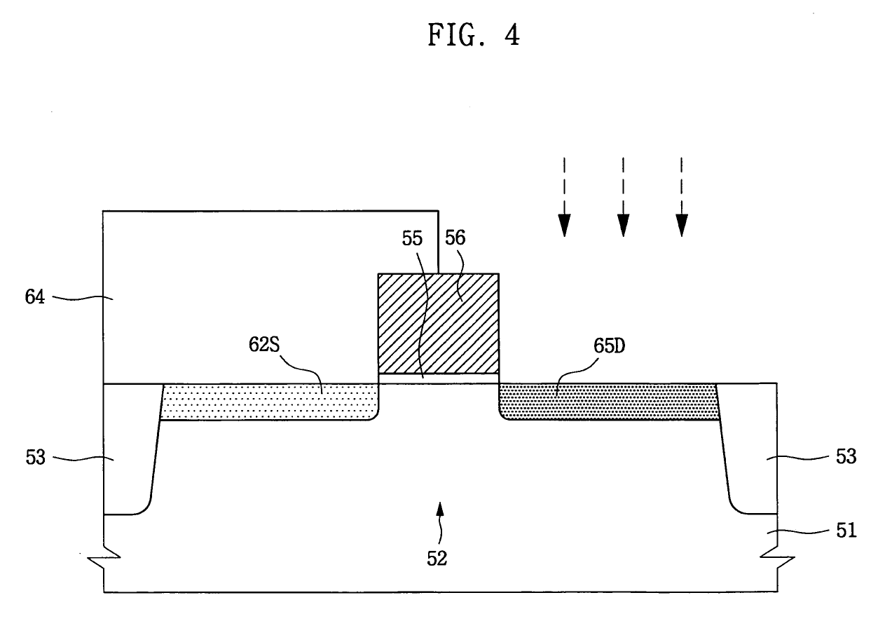

Referring to FIG. 4, a first mask pattern 64 may be formed on the substrate 51 having the source LDD region 62S. The first mask pattern 64 may cover the source LDD region 62S. In example embodiments, a top surface of the initial LDD region 62D may be exposed through an opening formed in the first mask pattern 64.

The second conductivity type impurity ions may be implanted into the initial LDD region 62D using the first mask pattern 64 as an ion implantation mask to form a drain LDD region 65D. The drain LDD region 65D may be formed to have the second conductivity type impurity ions in a concentration relatively higher than the source LDD region 62S. For example, the drain LDD region 65D may be formed to have the second conductivity type impurity ions in a concentration twice as high as the source LDD region 62S.

The drain LDD region 65D may be formed to a predetermined (or alternatively, a given) or desired depth from the surface of the active region 52. In addition, the drain LDD region 65D may be formed at substantially the same level as the source LDD region 62S. The drain LDD region 65D may be arranged at one side of the gate electrode 56.

Subsequently, the first mask pattern 64 may be removed.

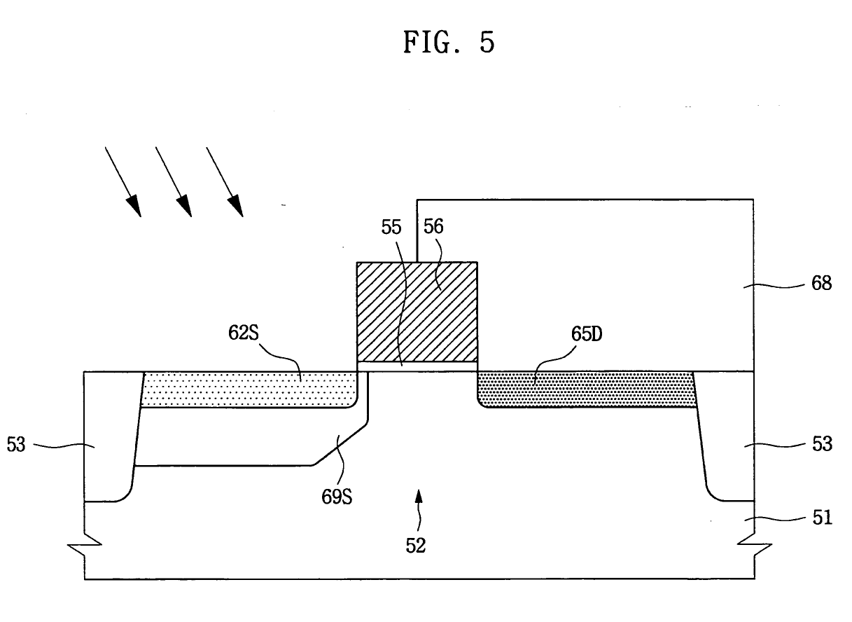

Referring to FIG. 5, a second mask pattern 68 may be formed on the substrate 51. The second mask pattern 68 may cover the drain LDD region 65D. In this example, a top surface of the source LDD region 62S may be exposed through an opening formed in the second mask pattern 68.

The first conductivity type impurity ions may be implanted into the active region 52 using the second mask pattern 68 as an ion implantation mask to form a first halo region 69S. The first halo region 69S may be formed to have the first conductivity type impurity ions in a concentration relatively higher than the active region 52. For example, the first conductivity type impurity ions may be implanted using a source containing boron difluoride (BF₂). The first conductivity type impurity ions may be implanted with various energies and at various angles using an ion implantation apparatus.

The first halo region 69S may be formed to surround the source LDD region 62S. In addition, the first halo region 69S may be formed to partially overlap the gate electrode 56.

Subsequently, the second mask pattern 68 may be removed.

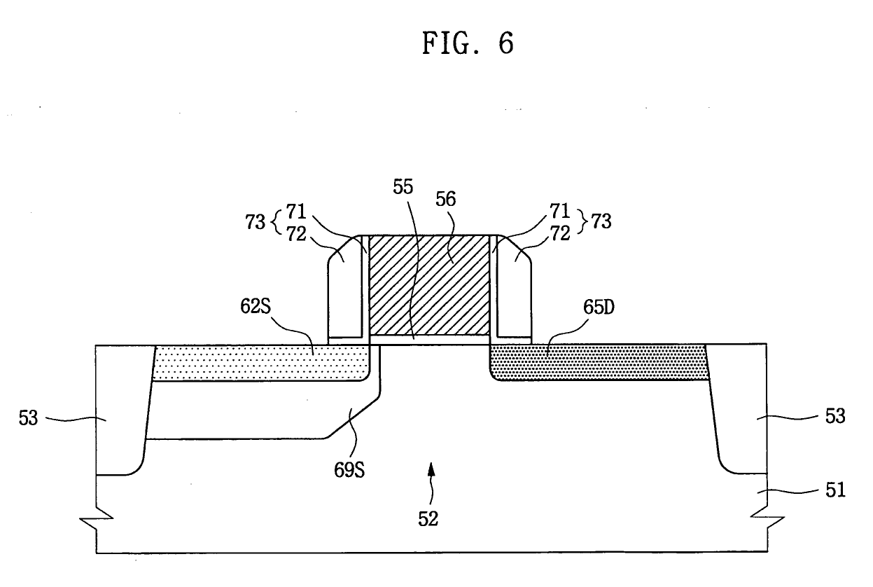

Referring to FIG. 6, spacers 73 may be formed on sidewalls of the gate electrode 56. The spacers 73 may include inner spacers 71 and outer spacers 72.

For example, a first insulating layer and a second insulating layer may be sequentially stacked on the substrate 51 having the gate electrode 56. The first insulating layer may be a silicon oxide layer such as a thermal oxide layer. The second insulating layer may be a nitride layer such as a silicon nitride layer. The second insulating layer and the first insulating layer may be anisotropically etched until the active region 52 is exposed to thereby form the spacers 73. In this example, the inner spacers 71 may be in contact with the sidewalls of the gate electrode 56. The outer spacers 72 may cover the inner spacers 71.

As a result, the source LDD region 62S and the drain LDD region 65D may be partially covered by the spacers 73.

Referring to FIG. 7, a source region 75S and a drain region 75D may be formed in the substrate 51 having the gate electrode 56 and the spacers 73. The source region 75S and the drain region 75D may be formed by implanting a relatively high concentration of second conductivity type impurity ions. The source region 75S and the drain region 75D may be formed to have the second conductivity type impurity ions in a concentration higher than the source LDD region 62S and the drain LDD region 65D.

As a result, the source LDD region 62S and the drain LDD region 65D may remain under the spacers 73.

The source region 75S and the drain region 75D may be disposed above the bottom of the isolation layer 53. Bottoms of the source region 75S and the drain region 75D may be disposed below the source LDD region 62S and the drain LDD region 65D. The source region 75S and the drain region 75D may be arranged outside the spacers 73.

The source region 75S may be in contact with the source LDD region 62S. In addition, the source region 75S may be partially in contact with the first halo region 69S. The drain region 75D may be in contact with the drain LDD region 65D.

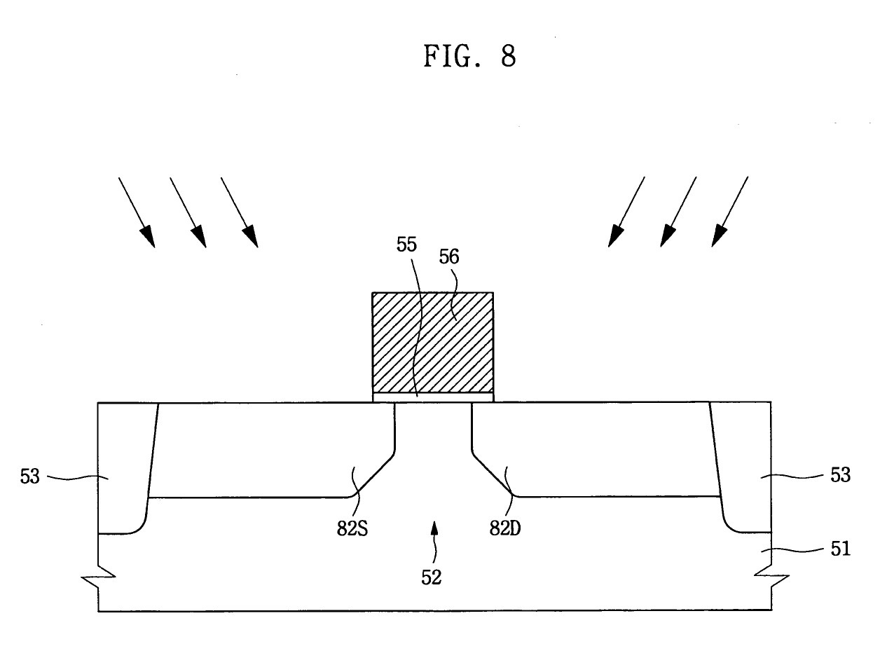

A method of fabricating a semiconductor device according to an example embodiment will now be described with reference to FIGS. 8 to 12.

Referring to FIG. 8, an isolation layer 53 defining an active region 52 may be formed in a predetermined (or alternatively, a given) or desired region of a substrate 51. Hereinafter, differences between previously described example embodiments with reference to FIGS. 2 to 7 will be described briefly.

The substrate 51 may be a semiconductor substrate such as a silicon wafer. The substrate 51 may have first conductivity type impurity ions. The first conductivity type may be an n− or p-type. A gate dielectric layer 55 and a gate electrode 56 may be sequentially formed on the substrate 51 having the isolation layer 53. The gate electrode 56 may be formed to cross the active region 52.

The first conductivity type impurity ions may be implanted into the substrate 51 having the gate electrode 56 to form an outer halo region 82S. The outer halo region 82S may be formed to have the first conductivity type impurity ions in a concentration relatively higher than the active region 52. For example, the first conductivity type impurity ions may be implanted using a source containing boron difluoride (BF₂). The first conductivity type impurity ions may be implanted with various energies and at various angles using an ion implantation apparatus.

The outer halo region 82S may be formed within the active region 52 at one side of the gate electrode 56. The outer halo region 82S may constitute a portion of the first halo region. As the outer halo region 82S is formed, a second halo region 82D may be formed within the active region 52 at the other side of the gate electrode 56. The outer halo region 82S and the second halo region 82D may be formed to partially overlap the gate electrode 56.

The second halo region 82D may be omitted. In addition, both the outer halo region 82S and the second halo region 82D may be omitted.

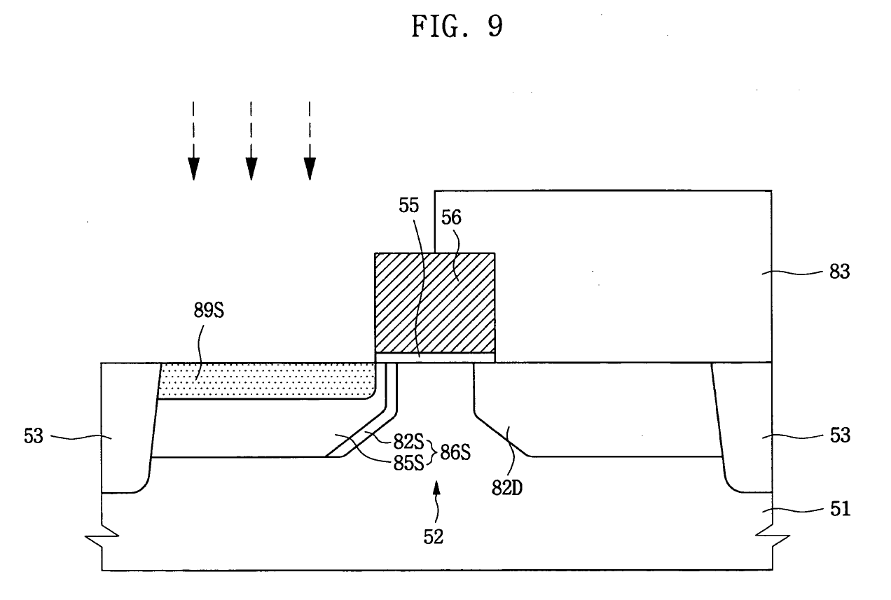

Referring to FIG. 9, a first mask pattern 83 may be formed on the substrate 51. The first mask pattern 83 may cover the second halo region 82D. In this example, a top surface of the outer halo region 82S may be exposed through an opening formed in the first mask pattern 83.

The first conductivity type impurity ions may be implanted into the active region 52 using the first mask pattern 83 as an ion implantation mask to form an inner halo region 85S. The inner halo region 85S may be formed to have the first conductivity type impurity ions in a concentration higher than the active region 52. For example, the first conductivity type impurity ions may be implanted using a source containing boron difluoride (BF₂). The first conductivity type impurity ions may be implanted with various energies and at various angles using an ion implantation apparatus.

The outer halo region 82S and the inner halo region 85S may constitute a first halo region 86S. However, the inner halo region 85S may constitute the first halo region 86S with the outer halo region 82S alternatively being omitted.

The first halo region 86S may be formed to have the first conductivity type impurity ions in a concentration relatively higher than the second halo region 82D.

Second conductivity type impurity ions may be implanted into the substrate 51 having the first halo region 86S to form a source LDD region 89S. The source LDD region 89S may be formed within the first halo region 86S. In addition, the source LDD region 89S may be arranged at one side of the gate electrode 56.

The second conductivity type may be opposite to the first conductivity type. For example, the second conductivity type may be p-type if the first conductivity type is the n-type, and may be n-type if the first conductivity type is p-type. For example, the second conductivity type impurity ions may be implanted using a source containing arsenic (As). The second conductivity type impurity ions may be implanted with various energies and at various angles using an ion implantation apparatus.

Subsequently, the first mask pattern 83 may be removed.

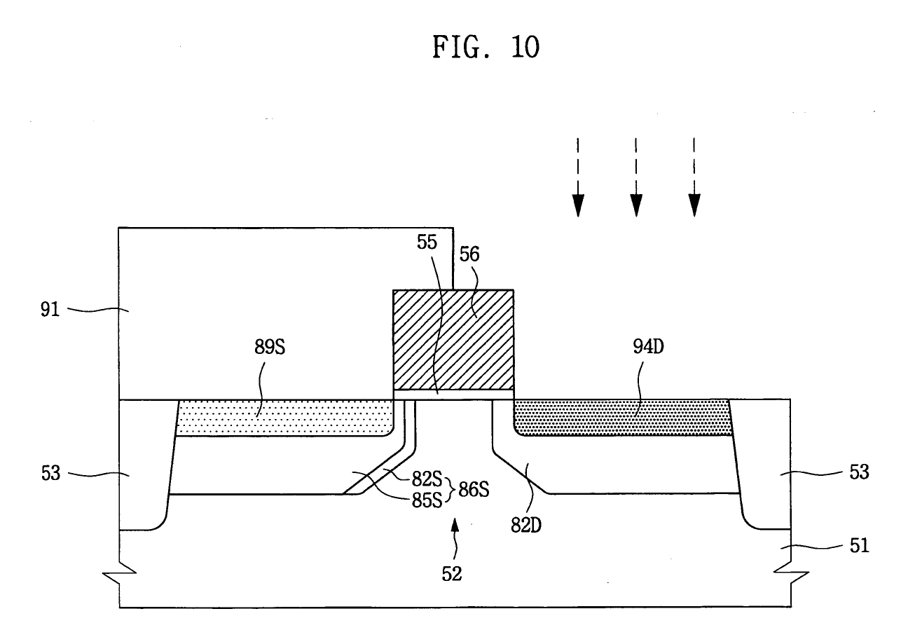

Referring to FIG. 10, a second mask pattern 91 may be formed on the substrate 51 having the source LDD region 89S. The second mask pattern 91 may cover the source LDD region 89S. In this example, a top surface of the second halo region 82D may be exposed through an opening formed in the second mask pattern 91.

The second conductivity type impurity ions may be implanted using the second mask pattern 91 as an ion implantation mask to form a drain LDD region 94D. The drain LDD region 94D may be formed to have the second conductivity type impurity ions in a concentration relatively higher than the source LDD region 89S. The drain LDD region 94D may be formed within the second halo region 82D. In addition, the drain LDD region 94D may be arranged at one side of the gate electrode 56.

Subsequently, the second mask pattern 91 may be removed.

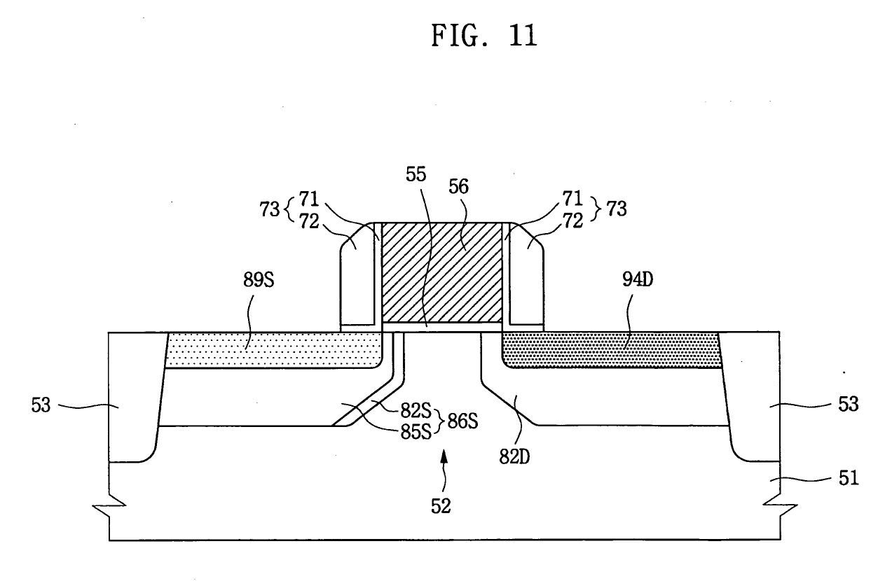

Referring to FIG. 11, spacers 73 may be formed on sidewalls of the gate electrode 56. The spacers 73 may include inner spacers 71 and outer spacers 72. The inner spacers 71 may be in contact with sidewalls of the gate electrode 56. The outer spacers 72 may cover the inner spacers 71.

As a result, the source LDD region 89S and the drain LDD region 94D may be partially covered by the spacers 73.

Referring to FIG. 12, a source region 75S and a drain region 75D may be formed in the substrate 51 having the gate electrode 56 and the spaces 73. The source region 75S and the drain region 75D may be formed by implanting a relatively high concentration of second conductivity type impurity ions. The source region 75S and the drain region 75D may be formed to have the second conductivity type impurity ions in a concentration relatively higher than the source LDD region 89S and the drain LDD region 94D.

Therefore, the source LDD region 89S and the drain LDD region 94D may remain under the spacers 73.

The source region 75S and the drain region 75D may be disposed above the bottom of the isolation layer 53. Bottoms of the source region 75S and the drain region 75D may be disposed at a lower level than the source LDD region 89S and the drain LDD region 94D. The source region 75S and the drain region 75D may be arranged outside the spacers 73.

The source region 75S may be in contact with the source LDD region 89S. In addition, the source region 75S may be partially in contact with the first halo region 86S.

The drain region 75D may be in contact with the drain LDD region 94D. In addition, the drain region 75D may be partially in contact with the second halo region 82D.

### EXAMPLES

Table 1 shows output resistance simulation results of transistors in accordance with experiments including example embodiments.

TABLE 1

| | C1: | C2: | C3: | C4: | C5: |
|---|---|---|---|---|---|
| Case | Vth(V) | Isat(A) | Ioff(A) | Rds(Ω) | N-Rds(Ω) |
| 1 | 0.4308 | 2.26E−06 | 1.06E−12 | 2200 K | 2200 K |
| 2 | 0.4390 | 2.89E−06 | 1.09E−12 | 4170 K | 5300 K |
| 3 | 0.4374 | 3.50E−06 | 1.13E−11 | 5430 K | 8400 K |

All transistors used for cases 1 to 3 were fabricated to have a gate dielectric layer of 2 nm thickness and a gate length (Lg) of 0.5 um.

Case 1 is the simulation result of arsenic (As) implanted into a source LDD region and a drain LDD region at a surface concentration of 1E15 atoms/cm² and boron difluoride (BF₂) implanted into first and second halo regions at a surface concentration of 4E13 atoms/cm². For example, such implantations may be similar to conventional methods of fabricating a transistor.

The first halo region was disposed within an active region of the transistor to surround the source LDD region, and the second halo region was disposed within the active region of the transistor to surround the drain LDD region.

Case 2 is the simulation result of arsenic (As) implanted into a source LDD region and a drain LDD region at a surface concentration of 1E15 atoms/cm² and boron difluoride (BF₂) implanted into a first halo region at a surface concentration of 4E13 atoms/cm² similar to a method of fabricating a transistor according to an example embodiment. In this case, a second halo region was omitted.

Case 3 is the simulation result of arsenic (As) implanted into a source LDD region at a surface concentration of 1E15 atoms/cm², arsenic (As) implanted into a drain LDD region at a surface concentration of 2E15 atoms/cm², and boron difluoride (BF₂) implanted into a first halo region at a surface concentrations of 4E13 atoms/cm², similar to a method of fabricating a transistor according to another example embodiment. In this case, a second halo region was omitted.

Referring to Table 1, C1 denotes threshold voltage Vth (V), C2 denotes drain saturation current Isat (A), C3 denotes off-current (A), C4 denotes output resistance Rds (Ω), and C5 denotes normalized output resistance N-Rds (Ω).

Referring to C5 of table 1, the normalized output resistance N-Rds obtained from case 1 is 2200 kΩ, from case 2 is 5300 kΩ, and from case 3 is 8400 kΩ. Thus, it can be easily seen that transistors according to example embodiments may have an output resistance 2.4 times to 3.8 times higher than conventional transistors.

According to example embodiments as described above, semiconductor devices having a first halo region, a source LDD region, and a drain LDD region are provided. The drain LDD region may have impurity ions in a concentration relatively higher than the source LDD region. The first halo region may surround the source LDD region. Accordingly, a channel region of the semiconductor device may have a sloped doping profile. Therefore, it may be possible to implement a semiconductor device having a high output resistance through suppression of channel length modulation.

Example embodiments have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device comprising:
an active region in a substrate and having first conductivity type impurity ions;
a gate electrode on the active region;
a source region disposed within the active region at a first side of the gate electrode;
a drain region disposed within the active region at a second side of the gate electrode;
a source lightly doped drain (LDD) region disposed within the active region, extending toward the gate electrode from the source region, and having second conductivity type impurity ions;
a drain LDD region disposed within the active region, extending toward the gate electrode from the drain region, and having the second conductivity type impurity ions in a concentration higher than the source LDD region; and
a first halo region disposed within the active region, surrounding the source LDD region, and having the first conductivity type impurity ions.

2. The semiconductor device according to claim 1, wherein the first halo region is partially in contact with the source region.

3. The semiconductor device according to claim 1, wherein the first halo region has the first conductivity type impurity ions in a concentration higher than the active region.

4. The semiconductor device according to claim 3, wherein the first halo region comprises:
an inner halo region in contact with the source LDD region; and
an outer halo region covering the inner halo region.

5. The semiconductor device according to claim 4, wherein the inner halo region has the first conductivity type impurity ions in a concentration higher than the outer halo region.

6. The semiconductor device according to claim 1, further comprising:
a second halo region disposed within the active region and surrounding the drain LDD region,
wherein the second halo region has the first conductivity type impurity ions in a concentration lower than the first halo region.

7. The semiconductor device according to claim 1, wherein:
the first conductivity type is one of an n-type and a p-type; and
the second conductivity type is the p-type if the first conductivity type is the n-type and the n-type if the first conductivity type is the p-type.

8. The semiconductor device according to claim 1, further comprising:
an isolation region in the substrate defining the active region.

9. The semiconductor device according to claim 1, further comprising:
spacers disposed on both sidewalls of the gate electrode.

10. A method of fabricating a semiconductor device, comprising:
forming a gate electrode on an active region of a substrate, the active region having first conductivity type impurity ions;
forming a source lightly doped drain (LDD) region of a second conductivity type impurity ions at a first side of the gate electrode;
forming a drain LDD region of the second conductivity type impurity ions in a concentration higher than the source LDD region at a second side of the gate electrode;
forming a first halo region surrounding the source LDD region;
forming spacers on both sidewalls of the gate electrode; and
forming a source region and a drain region within the active region outside the spacers.

11. The method of claim 10, wherein forming the source LDD region includes implanting the second conductivity type impurity ions into the active region at the first side of the gate electrode.

12. The method of claim 10, wherein forming the drain LDD region includes implanting the second conductivity type impurity ions into the active region at the second side of the gate electrode.

13. The method of claim 10, wherein forming the source LDD region includes forming an initial LDD region at the second side of the gate electrode.

14. The method of claim 13, wherein forming the drain LDD region includes implanting the second conductivity type impurity ions into the initial LDD region in a concentration higher than the source LDD region.

15. The method of claim 10, wherein forming the first halo region includes implanting the first conductivity type impurity ions into the active region at the first side of the gate electrode.

16. The method of claim 10, wherein forming the first halo region includes:
implanting the first conductivity type impurity ions into the active region at the first side of the gate electrode to form an outer halo region; and
implanting the first conductivity type impurity ions into the outer halo region to form an inner halo region.

17. The method of claim 10, further comprising forming a second halo region surrounding the drain LDD region.

18. The method of claim 17, wherein the forming the second halo region includes implanting the first conductivity type impurity ions into the active region at the second side of the gate electrode while forming the first halo region.

19. The method of claim 17, wherein the second halo region has a concentration of first conductivity type impurity ions lower than the first halo region.

20. The method of claim 10, wherein forming the first halo region comprises implanting the first conductivity type impurity ions into the active region at the first side of the gate electrode.

21. The method according to claim 10, wherein:
the first conductivity type is one of an n-type and a p-type; and
the second conductivity type is the p-type if the first conductivity type is the n-type and the n-type if the first conductivity type is the p-type.
